(19) United States
(12) Patent Application Publication
(10) Pub. No.: US 2009/0091546 A1
(43) Pub. Date: Apr. 9, 2009

(54) DISPLAY WITH TOUCH SCREEN PANEL AND METHOD OF MANUFACTURING THE SAME

(76) Inventors: Sun-Kyu Joo, Seoul (KR); Myung-Sub Lee, Seoul (KR); Ju-Hyeon Baek, Cheonan-si (KR); Ji-Young Jeong, Cheonan-si (KR); Sun-Kyo Jung, Asan-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/187,250

(22) Filed: Aug. 6, 2008

(30) Foreign Application Priority Data
Oct. 4, 2007 (KR) 10-2007-0099704

(51) Int. Cl. G06F 3/041; H01L 33/00

(52) U.S. Cl. 345/173; 438/30; 257/E33.062

(57) ABSTRACT

A display device with a built-in touch screen panel and a method of manufacturing the same are presented. The display includes a first substrate and a second substrate facing each other, a first sensing electrode and a second sensing electrode disposed on the first substrate and spaced apart from each other, and a conductive spacer disposed on the second substrate corresponding to each of the first and second sensing electrodes. The display device is less sensitive to misalignment between the first and second substrates during the manufacturing process compared to a conventional device, and therefore has a lower defect rate than the conventional device.

### CLAIM OF PRIORITY

The present application claims priority to Korean Patent Application No. 10-2007-0099704 filed on Oct. 4, 2007, and all benefits accruing therefrom under 35 U.S.C. §119, the contents of which are incorporated herein by reference in their entirety.

### BACKGROUND

1. Field of the Invention

The present disclosure relates to a display, and more particularly, to a display with a built-in touch screen panel and a method of manufacturing the same.

2. Related Art

In general, a touch screen panel is a device enabling a specific operation by touching a screen directly over a character, an icon, etc., with a human hand or an object without using a keyboard. A conventional touch screen panel is separately prepared from a display and then attached to the display, which increases a total thickness of the display. Therefore, in order not to increase the thickness, there has been proposed a display with a built-in touch screen panel in which a touch screen panel function is provided in the fabrication of the display.

In the conventional display with the built-in touch screen panel, a sensing electrode is disposed on a lower substrate where a thin film transistor (TFT) and a pixel electrode are provided, and a conductive spacer is disposed on an upper substrate where a color filter and a common electrode are provided. Therefore, the conductive spacer and the sensing electrode sense a touch position by a pressure applied thereto.

In the conventional display, when the upper and lower substrates are attached to each other, they are slightly misaligned, which leads to a misalignment between the sensing electrode and the conductive spacer. In particular, a surface of the conductive spacer contacting the sensing electrode does not have a flat shape but a substantially curved shape, so that an actual contact area between the conductive spacer and the sensing electrode is reduced. Therefore, the misalignment between the upper and lower substrates results in a sensing failure caused by insufficient contact of the sensing electrode and the conductive spacer.

### SUMMARY

Embodiments of the present disclosure provide a display (and method of manufacturing the same) with a built-in touch screen panel capable of preventing a sensing failure of a sensing electrode and a conductive spacer caused by a misalignment therebetween.

In accordance with an embodiment of the present disclosure, a display includes a first substrate and a second substrate facing each other, a first sensing electrode and a second sensing electrode disposed on the first substrate, and a conductive spacer disposed on the second substrate. The first and second sensing electrodes are spaced apart from each other, and the conductive spacer is disposed so as to correspond to each of the first and second sensing electrodes.

In various implementations, the first substrate may include a first sensing line arranged in one direction of the first substrate and a second sensing line intersecting the first sensing line, wherein the first and second sensing lines may be insulated from each other. The first and second sensing electrodes may be connected to the first and second sensing lines, respectively. The second sensing line may be provided for one or more unit pixels. The cross section of the conductive spacer may become wider as it extends from a region corresponding to a center of each of the first and second sensing electrodes toward a region corresponding to outer edges of the first and second sensing electrodes. The cross section of the conductive spacer may include a small width at a region between the first and second sensing electrodes. The cross section of the conductive spacer may include a maximum width at a region corresponding to the each center of the first and second sensing electrodes. The conductive spacer may include cross sections that may be spaced apart from each other and the cross sections may have wider regions corresponding to the each central portions of the first and second sensing electrodes. The conductive spacer may include two spacers that may be spaced apart from each other. The conductive spacer may be provided for one or more unit pixels and may be disposed on a black matrix. Portions of the first and second sensing electrodes may extend to cross each other.

In accordance with an embodiment of the present disclosure, a method of manufacturing a display includes forming first and second sensing lines and first and second sensing electrodes connected to the first and second sensing lines, respectively, on a first substrate. The first and second sensing lines extend in a first direction and a second direction, respectively, and are insulated from each other. The method may include forming a conductive spacer on a second substrate. The conductive spacer may be formed on a region corresponding to each of the first and second sensing electrodes. The method may include forming a cell gap spacer between the first and second substrates and forming a liquid crystal layer between the first and second substrates.

In accordance with an embodiment of the present disclosure, a display includes a lower substrate and an upper substrate facing each other, a first sensing electrode and a second sensing electrode disposed on the lower substrate, which are spaced apart from each other, and a conductive spacer disposed on the upper substrate to be corresponding to each of the first and second sensing electrodes.

In various implementations, the lower substrate may include a first sensing line arranged in one direction of the lower substrate and a second sensing line intersecting the first sensing line, wherein the first and second sensing lines may be insulated from each other. The first and second sensing electrodes may be connected to the first and second sensing lines, respectively. The second sensing line may be provided for every one or more unit pixels.

In various implementations, the conductive spacer may become wider from a region corresponding to each of the first and second sensing electrodes toward a region corresponding to outer edges of the first and second sensing electrodes. The conductive spacer may have a small width at a region between the first and second sensing electrodes. The conductive spacer may have a maximum width at a region corresponding to the centers of the outer edges of the first and second sensing electrodes. The conductive spacer may have cross sections that are spaced apart from each other and become wider from regions corresponding to the central portions of the first and second sensing electrodes toward outer edges of the first and second sensing electrodes. The conductive spacer may include two spacers that are spaced apart from each other, the two spacers respectively becoming wider from regions corresponding to the central portions of the first and second sensing electrodes toward outer edges of the first and second sensing electrodes. The conductive spacer may be provided for every one or more unit pixels, and is disposed on a black matrix. Portions of the first and second sensing electrodes may extend to cross each other.

In accordance with another embodiment of the present disclosure, a method of manufacturing a display includes forming first and second sensing lines and first and second sensing electrodes connected to the first and second sensing lines, respectively, on a first substrate, wherein the first and second sensing lines extend in one direction and another direction, respectively, and are insulated from each other. The method includes forming a conductive spacer on a second substrate, wherein the conductive spacer is wider from a region corresponding to each of the first and second sensing electrodes. The method includes forming a cell gap spacer between the first and second substrates and forming a liquid crystal layer between the first and second substrates.

In various implementations, forming the first and second sensing lines may include forming a plurality of gate lines extending in the one direction and the first sensing line spaced apart from the plurality of gate lines on the first substrate forming a gate insulating layer on the first substrate, and forming an active layer and an ohmic contact layer on a predetermined region of the gate insulating layer. forming a plurality of data lines extending in a direction intersecting the plurality of gate lines, and the second sensing line spaced apart from the plurality of data lines on the gate insulating layer, forming a passivation layer on the substrate, and etching a predetermined region of the passivation layer to form a plurality of contact holes, and forming a pixel electrode on the passivation layer, and forming the sensing electrode connected to the first and second sensing lines.

In various implementations, forming the conductive spacer may include forming a black matrix on a predetermined region of the second substrate, forming a protrusion extending along the sensing electrode in a region corresponding to the sensing electrode on the second substrate, and forming a color filter, and forming a conductive layer on the second substrate, and patterning the conductive layer to form a common electrode and a conductive spacer. The protrusion may be formed by a photolithography process using a mask exposing regions corresponding to respective central portions of the first and second sensing electrodes. The protrusion may include two protrusions spaced apart from each other.

These and other features and advantages of the present disclosure are more readily apparent from the detailed description of the embodiments set forth below taken in conjunction with the accompanying drawings.

### BRIEF DESCRIPTION OF THE DRAWINGS

FIG. 1 is a block diagram of a display in accordance with an embodiment of the present disclosure.

FIG. 2 is a plan view illustrating a display panel of a display in accordance with an embodiment of the present disclosure.

FIG. 3 is a cross-sectional view taken along line I-I′ of FIG. 2.

FIG. 4 is a cross-sectional view taken along line II-II of FIG. 2.

FIGS. 5A and 5B are plan views illustrating conductive spacers in accordance with an embodiment of the present disclosure.

FIG. 6 is a cross-sectional view taken along line II-II′ of FIG. 2 illustrating a sectional structure of the conductive spacer in accordance with an embodiment of the present disclosure.

FIG. 7 is a plan view illustrating examples of misalignment contacts between a conductive spacer and first and second sensing electrodes.

FIGS. 8A, 8B, 9A, 9B, 10A, 10B, 11A, 11B, 12A and 12 B are cross-sectional views illustrating a method of manufacturing a lower substrate of a display in accordance with an embodiment of the present disclosure.

FIGS. 13A, 13B, 14A, 14B, 15A, 15B, 16A, 16B, 17A, 17B, 18A and 18B are cross-sectional views illustrating a method of manufacturing an upper substrate of a display in accordance with an embodiment of the present disclosure.

FIG. 19 is a plan view of a mask used in various embodiments of the present disclosure.

FIG. 20 is a view illustrating shapes of first and second sensing electrodes in accordance with embodiments of the present disclosure.

### DETAILED DESCRIPTION OF EMBODIMENTS

Hereinafter, specific embodiments will be described in detail with reference to the accompanying drawings. The invention may, however, be embodied in many different forms and should not be construed as being limited to the embodiments set forth herein. Rather, these embodiments are provided so that this disclosure will be thorough and complete, and fully convey the concept of the invention to those skilled in the art.

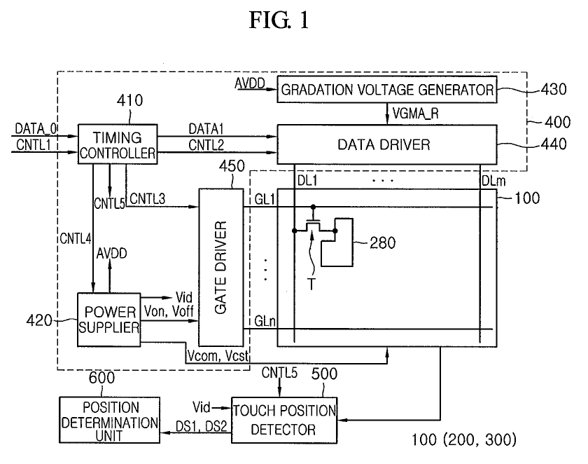

FIG. 1 is a block diagram of a display in accordance with an embodiment of the present disclosure. Referring to FIG. 1, the display, in one embodiment, includes a display panel 100, a panel driver 400, a touch position detector 500 and a position determination unit 600. The display panel 100 includes a lower substrate where a thin film transistor (TFT), a pixel electrode and a sensing electrode are provided, an upper substrate 300 where a color filter, a common electrode and a conductive spacer are provided, and a liquid crystal layer (not shown) provided between the lower substrate 200 and the upper substrate 300.

In the lower substrate 200, a plurality of gate lines GL1 through GLn extend in one direction and a plurality of data lines DL1 through DLm extend in another direction. Pixels are disposed at every intersection of the plurality of gate lines GL1 through GLn and the plurality of data lines DL1 through DLm. In each of the pixels, a TFT (T) acting as a switching component and a pixel electrode 280 are disposed. The TFT (T) includes a gate electrode connected to the gate line GL, a source electrode connected to the data line DL and a drain electrode connected to the pixel electrode 280. The lower substrate 200 further includes a plurality of first sensing lines (not shown), a plurality of second sensing lines (not shown) and a plurality of sensing electrodes (not shown) connected to the first and second sensing lines for performing a touch screen panel function. The first sensing line may extend in the same direction as the gate line GL, and the second sensing line may extend in the same direction as the data line DL. Here, the first and second sensing lines intersect each other, and are electrically insulated from each other. An initial driving voltage Vid having a predetermined voltage level is applied to the first and second sensing lines, and the first and second sensing lines are connected to the touch position determination unit 500. The first and second sensing lines may be provided for each of red (R), green (G) and blue (B) pixels or for every predetermined number of pixels. For example, the first and second sensing lines may be provided for every one or more unit pixels, wherein the unit pixel may include, for example, three pixels.

The upper substrate 300 provided with the color filter and the common electrode is disposed facing the lower substrate 200 and is attached to the lower substrate 200. The liquid crystal layer (not shown) is disposed between the upper and lower substrates. The upper substrate 330 may include a color filter substrate where color filters corresponding to respective pixels are provided. However, the color filters may be disposed on the lower substrate 200. The upper substrate 300 further includes a plurality of conductive spacers (not shown) so as to perform a touch screen panel function. The conductive spacer electrically contacts the sensing electrode on the lower substrate 200 by an external pressure applied from the above. The conductive spacer may be provided for each of red (R), green (G) and blue (B) pixels or for every three pixels.

In one implementation, as the sensing electrodes connected to the first and second sensing lines on the lower substrate 200 electrically contact the conductive spacers of the upper substrate 300 by an external pressure, x and y coordinates of a touch position to which the external pressure is applied may be determined by a voltage level variation of the initial driving voltage Vid applied to the first and second sensing lines.

The panel driver 400, in one embodiment, includes a timing controller 410, a power supplier 420, a gradation voltage generator 430, a data driver 440 and a gate driver 450.

The timing controller 410 controls an overall operation of the display. As an original data signal DATA_0 of R, G and B and a first control signal CNTL1 are supplied from a host system such as a graphic controller (not shown), the timing controller 410 outputs a first data signal DATA 1, a second control signal CNTL2, a third control signal CNTL3, a fourth control signal CNTL4 for displaying an image on the display panel 100. Specifically, the first control signal CNTL1 may include a main clock signal MCLK, a horizontal synchronization signal HSYNC and a vertical synchronization signal VSYNC. The second control signal CNTL2 includes a horizontal start signal STH, an inversion signal REV and a data load signal TP for controlling the data driver 440. The third control signal CNTL3 includes a vertical start signal STV, a clock signal CK and an output enable signal OE for controlling the gate driver 450. The fourth control signal CNTL4 includes a clock signal CLK and an inversion signal REV for controlling the power supplier 420.

In one implementation, the timing controller 410 applies the first data signal DATA1 of R′, G′ and B′, which is obtained by controlling an output timing of the original data signal DATA_0 of R. G and B, to the data driver 440. The timing controller 410 further outputs a fifth control signal CNTL5 for controlling the touch position detector 500. The fifth control signal CNTL5 includes a clock signal controlling the initial driving voltage Vid outputted from the power supplier 420 to be supplied to the first and second sensing lines.

The power supplier 420 is responsive to the fourth control signal CNTL4 outputted from the timing controller 410, thereby outputting common voltages Vcom and Vcst to be supplied to the display panel 100, the initial driving voltage Vid to be supplied to the lower substrate 200 so as to perform the touch screen function, an analog driving voltage AVDD to be supplied to the gradation voltage generator 430, and gate on/off voltages Von and Voff to be supplied to the gate driver 450.

In one implementation, by using the analog driving voltage AVDD supplied from the power supplier 420 as a reference voltage, the gradation voltage generator 430 outputs a plurality of reference gradation voltages VGMA_R corresponding to gradation levels based on division resistors having a resistance ratio to which gamma curve is applied.

The data driver 440 generates a gradation voltage VGMA on the basis of the reference gradation voltage VGMA_R outputted from the gradation voltage generator 430. Further, the data driver 440 converts the digital type first data signal DATA1 supplied per line into a data signal on the basis of the second control signal CNTL2 and the gradation voltage VGMA; and controls an output timing of the data signal and outputs them to the data lines DL1 through DLm.

The gate driver 450 generates gate signals according to the third control signal CNTL3 outputted from the timing controller 410 and the gate on/off voltages Von and Voff outputted from the power supplier 420, and then outputs the generated gate signals to the gate lines GL1 through GLm in sequence.

The touch position detector 500 detects a position coordinate of a point to which an external pressure is applied. That is, the conductive spacer disposed on the upper substrate 300 contacts the sensing electrode of the lower substrate 200 by the external pressure, and detects the voltage level variation of the initial driving voltage Vid applied to the first and second sensing lines. In this way, x and y coordinates are determined. As such, the touch position detector 500 includes a voltage supply control unit (not shown) configured to supply the initial driving voltage Vid to the first and second sensing lines according to the fifth control signal CNTL5, and a data sampling unit (not shown) configured to detect the variation of the initial driving voltage Vid in each of the first and second sensing lines to output a first detection signal DS1 and a second detection signal DS2, respectively. The touch position detector 500 may be provided in the data driver 440.

In one implementation, the position determination unit 600 is adapted to determine a touch position of the display panel to which the external pressure is applied by combining the x and y coordinates that are respectively determined by the first and second detection signals DS1 and DS2 outputted from the touch position detector 500.

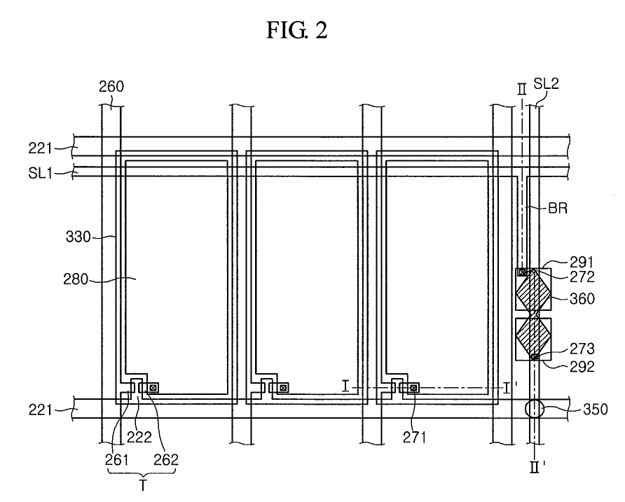

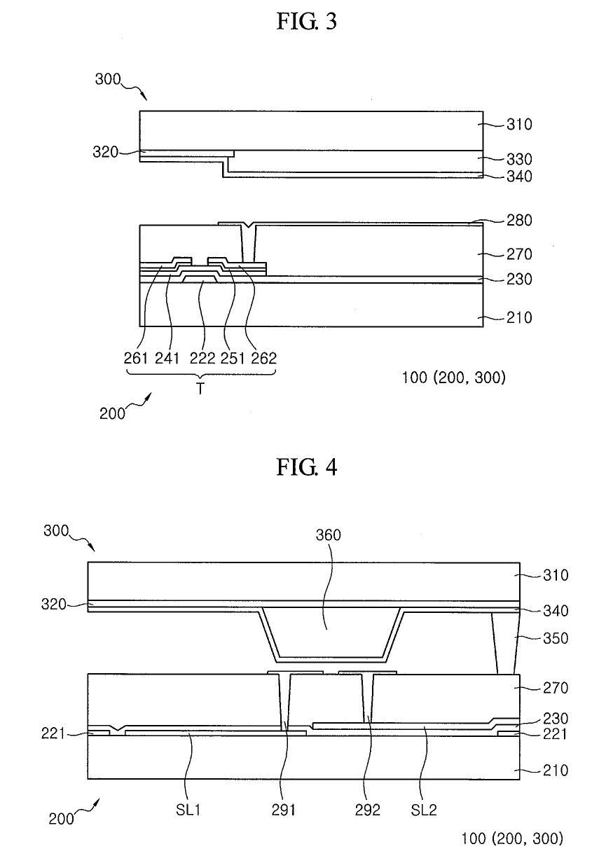

FIG. 2 is a plan view illustrating a display panel in accordance with an embodiment of the present disclosure, FIG. 3 is a cross-sectional view taken along line I-I′ of FIG. 2, and FIG. 4 is a cross-sectional view taken along II-II′ of FIG. 2. In one aspect, this particular embodiment illustrates a case where a sensing electrode and a conductive spacer are provided for every three pixels.

Referring to FIGS. 2, 3 and 4, a display panel 100 of a display having a built-in touch screen panel in accordance one embodiment includes a lower substrate 200, an upper substrate 300 and a liquid crystal layer (not shown) provided between the lower and upper substrates 200 and 300. Herein, the lower and upper substrates 200 and 300 are disposed facing each other.

In one embodiment, the lower substrate 200 includes: a plurality of gate lines 221 extending in one direction over a first insulating substrate 210; a plurality of data lines 260 extending in another direction intersecting the gate lines 221; a pixel electrode 280 provided in each pixel region defined by the gate lines 221 and the data lines 260; and a TFT (T) connected to the gate line 221, the data line 260 and the pixel electrode 280. The lower substrate 200 further includes: a first sensing line SL1 spaced apart from the gate line 221 and extending in one direction; a second sensing line SL2 spaced apart from the data line 260 and extending in another direction; a first sensing electrode 291 connected to the first sensing line SL1; and a second sensing electrode 292 connected to the second sensing line SL2.

The gate line 221 may extend, for example, in a horizontal direction, and a portion of the gate line 221 protrudes to form a gate electrode 222. A gate insulating layer 230 is disposed on an entire surface including the gate line 221. The gate insulating layer 230 may have a mono-layered structure or a multilayered structure including silicon oxide (SiO₂) or a silicon nitride (SiNx).

An active layer 241 formed of a semiconductor material such as amorphous silicon is disposed on the gate insulating layer 230 over the gate electrode 222. An ohmic contact layer 251 is disposed on the active layer 241. The ohmic contact layer 251 is formed of a semiconductor material such as silicide or n+ hydrogenated amorphous silicon heavily doped with n-type impurities. The ohmic contact layer 251 may be removed at a channel region between a source electrode 261 and a drain electrode 262.

The data line 260 is disposed over the gate insulating layer 230. The data line 260 extends in a direction intersecting the gate line 221. A region where the data line 260 and the gate line 221 intersect each other is defined as a pixel region. A portion of the data line 260 protrudes to an upper portion of the ohmic contact layer 251 to form the source electrode 261. The drain electrode 262 is disposed on the ohmic contact layer 251 such that it is spaced apart from the source electrode 261.

A passivation layer 270 is disposed over an entire surface including the gate line 221 and the data line 260. The passivation layer 270 may include an inorganic insulating layer or an organic insulating layer. First to third contact holes 271, 272 and 273 are provided in the passivation layer 270. The first contact hole 271 exposes a predetermined portion of the drain electrode 262, the second contact hole 272 exposes a portion of the first sensing line SL1, and the third contact hole 273 exposes a portion of the second sensing line SL2.

The pixel electrode 280 is disposed on the passivation layer 270. The pixel electrode 280 is formed of a transparent conductive material such as indium tin oxide (ITO) or indium zinc oxide (IZO). The pixel electrode 280 is connected to the drain electrode 262 through the first contact hole 271.

The first sensing line SL1 is disposed to be spaced apart from the gate line 221 by a predetermined distance. The first sensing line SL1 may be simultaneously formed with the gate line 221. A branch line BR branched from the first sensing line SL1 may be spaced apart from the second sensing line SL2 by a predetermined distance and extend in the same direction as the extension direction of the second sensing line SL2. However, the branch line BR does not extend as far as the second sensing line SL2 and extends only to be connected to the first sensing electrode 291.

The second sensing line SL2 is disposed to be spaced apart from the data line 260 by a predetermined distance, and the second sensing line SL2 is provided for every predetermined number of pixels. For example, the second sensing line SL2 may be disposed between a blue pixel and a red pixel. The second sensing line SL2 may be simultaneously formed with the data line 260.

The first sensing electrode 291 is connected to the branch line BR of the first sensing line SL1 through the second contact hole 272, and the second sensing electrode 292 is connected to the second sensing line SL2 through the third contact hole 273. The first and second sensing electrodes 291 and 292 may be simultaneously formed with the pixel electrode 280 to be spaced apart from the pixel electrode 280 by predetermined distances.

The upper substrate 300, in one embodiment, includes a black matrix 320, a color filter 330 and a common electrode 340 disposed on a second insulating substrate 310. The upper substrate 300 further includes a cell gap spacer 350 and a conductive spacer 360.

The black matrix 320 is provided on the upper substrate 300 except for a sub pixel region. For example, the black matrix 320 is disposed on a region of the upper substrate 300 corresponding to the gate line 221, the data line 260, the TFT (T) and the first and second sensing lines SL1 and SL2 of the lower substrate 200. Hence, the black matrix 320 prevents light leakage through regions other than the pixel region, and also prevents light interference between adjacent pixel regions. The black matrix 320 is formed of a photosensitive organic material with black pigment added. The black pigment may include carbon black or titanium oxide.

In one implementation, the red (R), green (G) and blue (B) filters of which boundaries are the black matrices 320 are repeatedly arranged to form the color filter 330. The color filter 330 gives a corresponding color to light which is incident from a light source and passes through the liquid crystal layer (not shown). The color filter 330 may be formed of a photosensitive organic material.

The common electrode 340 may be formed of a transparent conductive material, e.g., ITO or IZO, and provided on the second insulating substrate 310 including the black matrix and the color filter 330.

The cell gap spacer 350 maintains a space between the lower and upper substrates 200 and 300. The cell gap spacer 350 is arranged for each pixel or for every predetermined number of pixels, for example, three pixels. The cell gap spacer 350 may be disposed on the black matrix 320 between the blue color filter 330 and the red color filter 330.

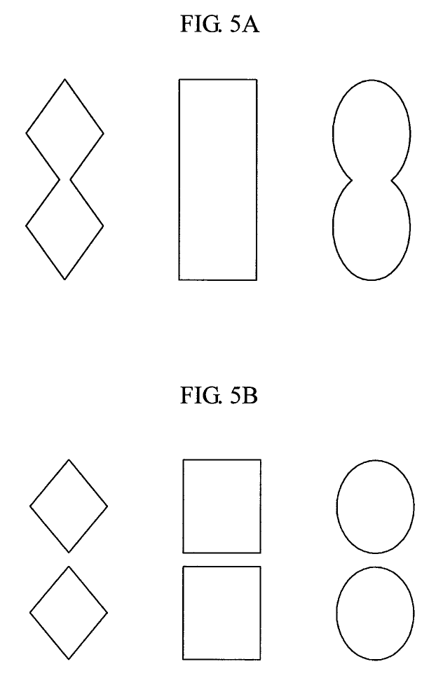

The conductive spacer 360, in one embodiment, is arranged for every predetermined number of pixels. For instance, the conductive spacer 360 is disposed on the black matrix 320 between the blue pixel and the red pixel, and is positioned corresponding to the first and second sensing electrodes 291 and 292 of the lower substrate 200. The conductive spacer 360, in one embodiment, extends from regions corresponding to respective central portions of the first and second sensing electrodes 291 and 292 toward regions corresponding to four edges of each of the first and second sensing electrodes 291 and 292. The conductive spacer 360 extends from the regions corresponding to the respective central portions of the first and second sensing electrodes 291 and 292 toward the center of each of the four edges of the first and second sensing electrodes 291 and 292, whereby the conductive spacer 360 has the maximum width. Therefore, a width of the conductive spacer 360 is small at a region between the first and second sensing electrodes 291 and 292, and gradually increases toward each of the first and second sensing electrodes 291 and 292. Two spacers spaced apart from each other may be disposed such that they respectively correspond to the central portions of the first and second sensing electrodes 291 and 292 and may be connected to each other through a conductive layer. Various shapes of the conductive spacer 360 are exemplarily illustrated in FIGS. 5A and 5B.

Referring to FIG. 5A, the conductive spacer 360 may have the shape of two joined diamonds such that its width is small at a middle region between the first and second sensing electrodes 291 and 292, gradually increases toward the first and second sensing electrodes 291 and 292, and then gradually decreases again. Alternatively, the conductive spacer 360 may have the shape of a rectangle such that it extends from a top end of the first sensing electrode 291 to a bottom end of the second sensing electrode 292. Alternatively, the conductive spacer 360 may have the shape of two joined circles such that its width is small at a middle region between the first and second sensing electrodes 291 and 292 and gradually increases toward the first and second sensing electrodes 291 and 292.

In various implementations, if the conductive spacer 360 is designed such that two conductive spacers are spaced apart from each other like the separated first and second sensing electrodes 291 and 292, each may also have the shape of diamond, rectangle and circle, as illustrated in FIG. 5B. Such a conductive spacer 360 may be formed through a photolithography process using a mask, for example, having two light transmitting parts exposing both a region corresponding to the central portion of the first sensing electrode 291 and a region corresponding to the central portion of the second sensing electrode 292. The conductive spacer 360 may have a variety of shapes depending on a shape of an exposed part of a mask, a distance between a substrate and the mask, and so on.

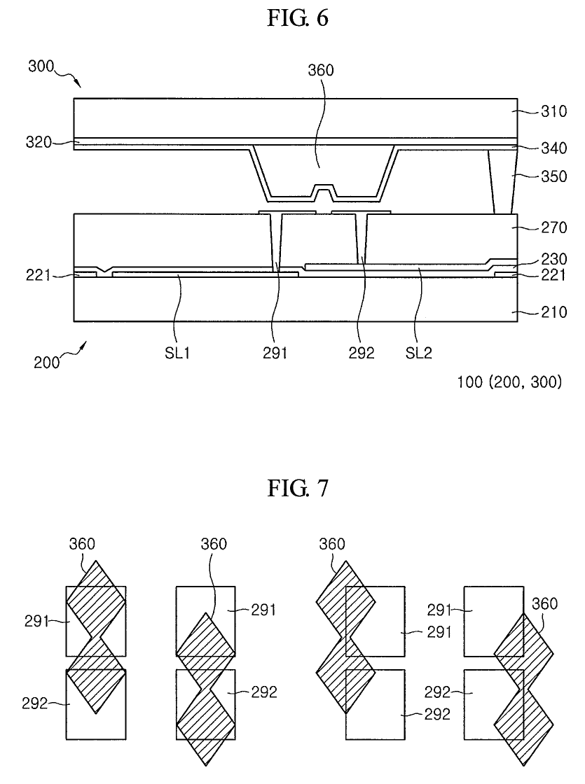

In a sectional view of the conductive spacer 360, a portion of the conductive spacer 360 corresponding to one end of the first sensing electrode 291 and another portion corresponding to the other end of the second sensing electrode 292 may have the same height as illustrated in FIG. 4. Alternatively, a portion of the conductive spacer 360 corresponding to the first and second sensing electrodes 291 and 292 may have a lower height than another portion between the first and second sensing electrodes 291 and 292 as illustrated in FIG. 6.

Consequently, in one embodiment, even if the misalignment occurs between the conductive layer and the first and second sensing electrodes 291 and 292, a sensing failure will not occur because the conductive spacer 360 is shaped such that it extends from regions corresponding to the central portions of the first and second sensing electrodes 291 and 292 toward regions corresponding to outer edges of the first and second sensing electrodes 291 and 292. In other words, even though the conductive spacer 360 is misaligned with the first and second sensing electrodes 291 and 292 to the above, below, left or right side thereof, as illustrated in FIG. 7, a sensing failure will not occur.

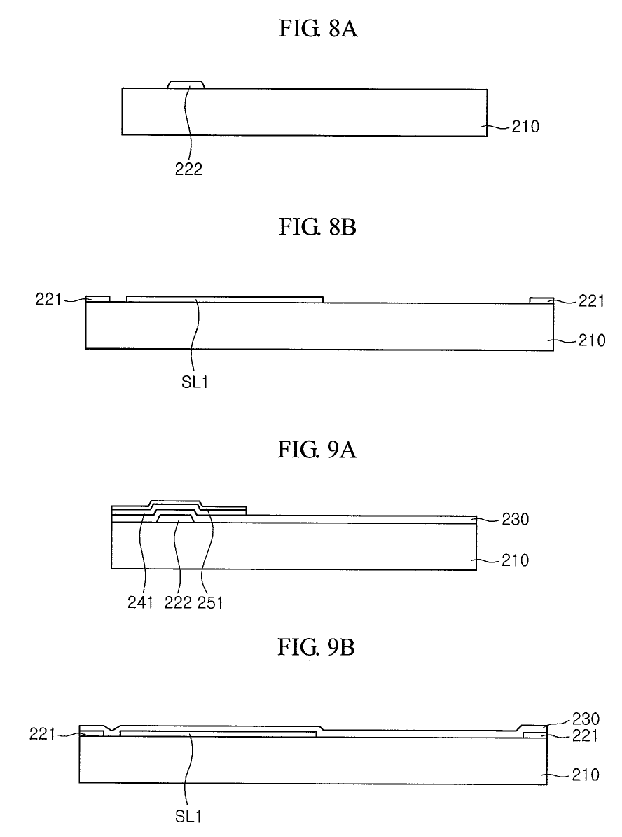

FIGS. 8 through 12 are cross-sectional views illustrating a method of manufacturing a lower substrate of a display with a built-in touch screen panel in accordance with one embodiment. Specifically, FIGS. 8A, 9A, 10A, 11A and 12A are cross-sectional views taken along line I-I′ of FIG. 2, and FIGS. 8B, 9B, 10B, 11B and 12B are cross-sectional views taken along line II-II′ of FIG. 2.

Referring to FIGS. 8A and 8B, a first conductive layer is formed on an insulating transparent substrate 210 formed of glass, quartz, ceramic or plastic. The first conductive layer is patterned through a photolithography process using a first mask, thereby forming a plurality of gate lines 221 arranged to be spaced apart by predetermined intervals in one direction and gate electrodes 222 protruding from the gate lines 221. Further, a first sensing line SL1 is formed, which is spaced apart from the gate line 221 by a predetermined distance, and a branch line BP branched from the first sensing line SL1 is formed.

Referring to FIGS. 9A and 9B, a gate dielectric layer 230, a first semiconductor layer and a second semiconductor layer are sequentially formed on an entire surface of the substrate 210. The second semiconductor layer and the first semiconductor layer are then patterned through a photolithography process using a second mask, and thereby an active layer 241 and an ohmic contact layer 251 are formed. The active layer 241 and the ohmic contact layer 251 are formed to cover the gate electrode 222. The gate insulating layer 230 may be formed of an inorganic insulating material including silicon oxide and silicon nitride. The first semiconductor layer may be formed of amorphous silicon, and the second semiconductor layer may be formed of n+ hydrogenated amorphous silicon heavily doped with n-type impurities.

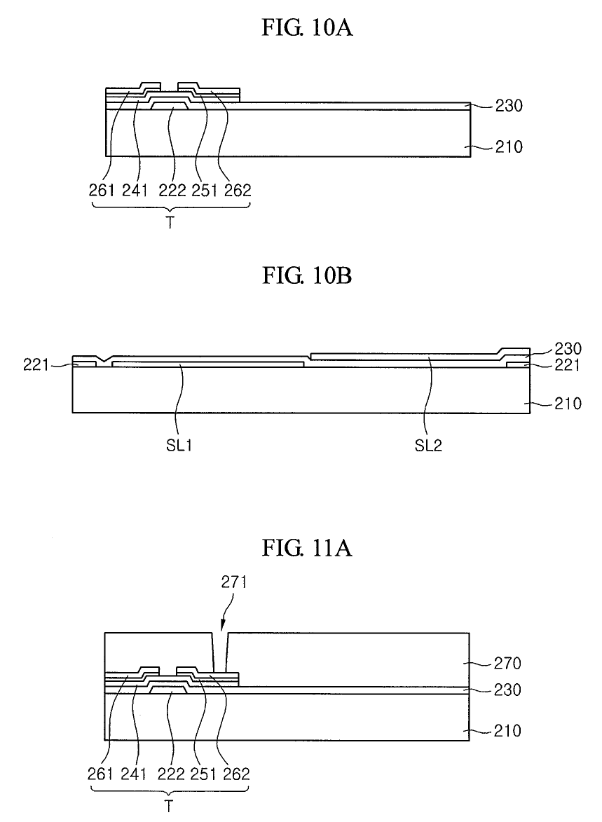

Referring to FIGS. 10A and 10B, a second conductive layer is formed on an entire surface of the substrate 210. Thereafter, the second conductive layer is patterned by a photolithography process using a third mask, and thereby a data line 260 having a source electrode 261 and a drain electrode 262 is formed. Herein, the data line 260 extends in a direction perpendicular to the extension direction of the gate line 221. At the same time when the data line 260 is formed, a second sensing line SL2, which is spaced apart from the data line 260 by a predetermined distance, is formed. The second sensing line SL2 is formed, for example, for every three pixels.

Referring to FIGS. 11A and 11B, a passivation layer 270 is formed over an entire surface of the substrate 210. Afterwards, the passivation layer 270 is partially etched by a photolithography process using a fourth mask, and thereby a first contact hole 271 exposing the drain electrode 262, a second contact hole 272 exposing the first sensing line SL1, and a third contact hole 273 exposing the second sensing line SL2 are formed.

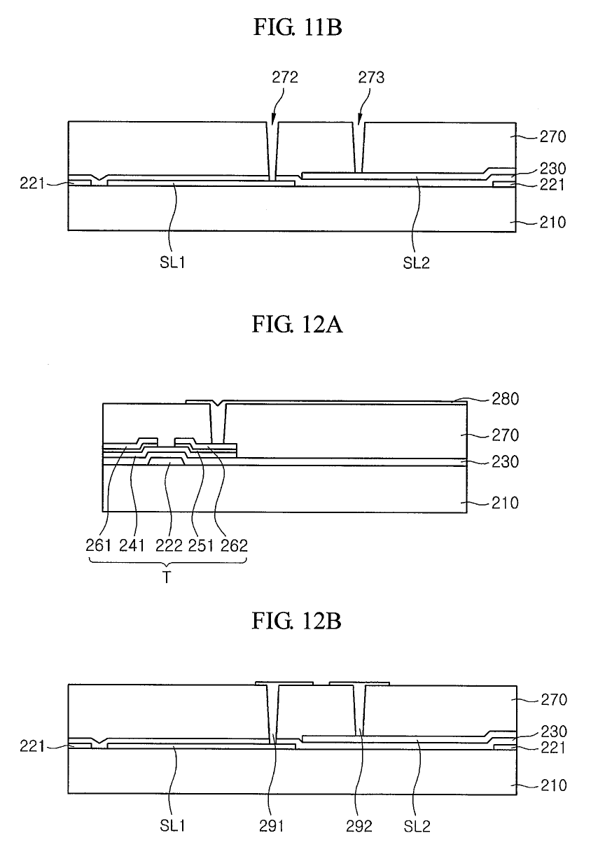

Referring to FIGS. 12A and 12B, a third conductive layer is formed on the passivation layer 270. Subsequently, the third conductive layer is patterned by a photolithography process using a fifth mask, and thereby a pixel electrode 280, a first sensing electrode 291 and a second sensing electrode 292 are formed. The pixel electrode 280 is formed in a region defined by intersection of the gate line 221 and the data line 260, and is connected to the drain electrode 262 through the first contact hole 271. The first and second sensing electrodes 291 and 292 are electrically connected to the first and second sensing lines SL1 and SL2 through the second and third contact holes 272 and 273, respectively. The first and second sensing electrodes 291 and 292 are spaced apart from each other by a predetermined distance. Since the first and second sensing electrodes 291 and 292 are formed in a region except for the pixel region, they are not electrically connected to the pixel electrode 280. The third conductive layer may be formed using a transparent conductive layer including ITO and IZO.

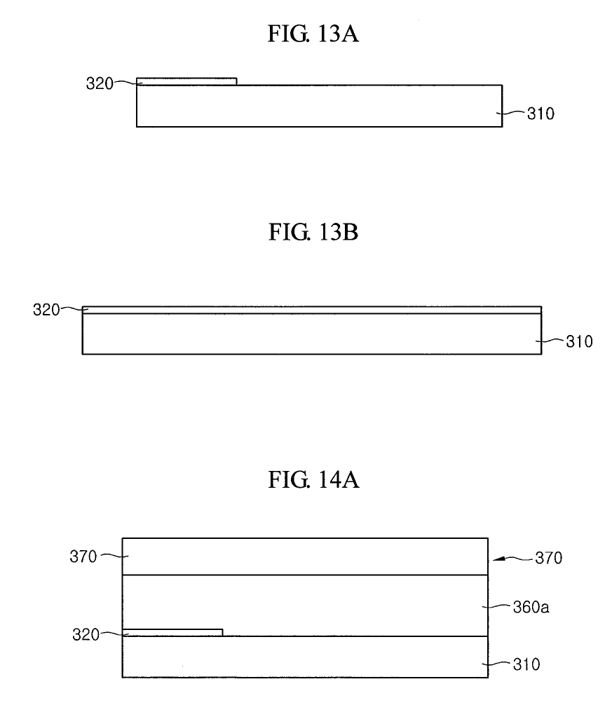

FIGS. 13 through 18 are cross-sectional views illustrating a method of manufacturing an upper substrate of a display with a built-in touch screen panel in accordance with one embodiment. Specifically, FIGS. 13A, 14A, 15A, 16A, 17A and 18A are cross-sectional views taken along line I-I′ of FIG. 2, and FIGS. 13B, 14B, 15B, 16B, 17B and 18B are cross-sectional views taken along line II-II′ of FIG. 2.

Referring to FIGS. 13A and 13B, a black matrix 320 is formed on a predetermined region of an insulating transparent substrate 310 formed of glass, quartz, ceramic, plastic or the like. The black matrix 320 can be formed by forming a photosensitive organic material including black pigment on the transparent substrate 310 and then performing exposure and development process using a first mask. The black pigment may include carbon black or titanium oxide. The black matrix 320 is formed in a region except for the pixel region. That is, the black matrix 320 is formed in regions corresponding to the gate line 221, the data line 260, and the first and second sensing lines SL1 and SL2 of the lower substrate 200. The black matrix 320 separates the color filters from one another, and blocks light passing through liquid crystal cells in a region which is not controlled by the pixel electrode 280 of the lower substrate 200, which improves the contrast ratio of the display.

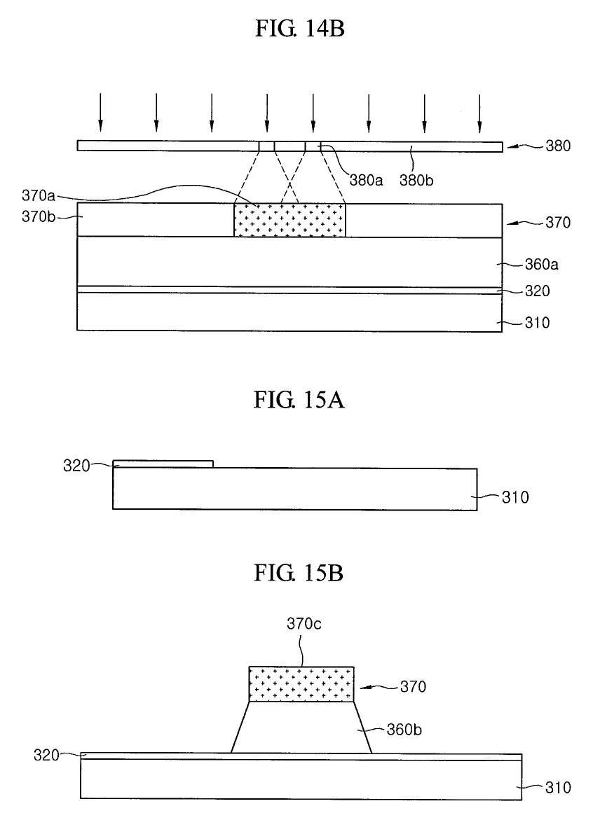

Referring to FIGS. 14A and 14B, an insulating layer 360a is formed on the substrate 310 with the black matrix 320 formed. The insulating layer 360a is formed using an organic insulating layer and an inorganic insulating layer. After forming a photosensitive layer 370 on the insulating layer 360a, an exposure process is performed using a predetermined second mask 380. The second mask has a light transmitting part 380a in a portion of a region corresponding to the first and second sensing electrodes 291 and 292 of the lower substrate 200. In detail, the light transmitting part 380a of the second mask 380 may be formed in a region corresponding to the central portions of the first and second sensing electrodes 291 and 292, as illustrated in FIG. 19.

In one embodiment, light is incident through the light transmitting part 380a of the second mask 380 to expose a predetermined region of the photosensitive layer 370. An exposed region 370a may be formed according to a shape of the light transmitting part 380a of the second mask 380 and a distance between the second mask 380 and the photosensitive layer 370. For example, if the distance between the second mask 380 and the photosensitive layer 370 corresponds to a distance that enables light incident through two light transmitting parts 380a to be superimposed, the photosensitive layer 370 disposed in a region between the two light transmitting parts 380a is also exposed. This results in formation of a conductive spacer having shapes such as the ones shown in FIG. 5A.

In a case where the light transmitting part 380a is formed in the shape of a diamond, the exposed region 370a may be formed in diamond shape such that it is rather narrow at a region corresponding to the central portions of the two light transmitting parts 380a, gradually increases toward both sides thereof, and then gradually decreases again. In another embodiment, the exposed region 370a may be formed in the shape of a rectangle such that it extends from one side of the photosensitive layer 370 to the other side. In yet another embodiment, the exposed region 370a may be formed in the shape of a circle such that its width is small at a region corresponding to the central portions of the two light transmitting parts 380a and gradually increases toward both sides thereof.

On the other hand, if the distance between the second mask 380 and the photosensitive layer 370 corresponds to a distance that does not enable the light incident through the two light transmitting parts 380a to be superimposed, the photosensitive layer 370 between the two light transmitting parts 380a is not exposed. This method results in formation of conductive spacers having shapes such as the ones shown in FIG. 5B. Therefore, depending on the shape of the light transmitting part 380a, the exposed region 370a may be formed in the shape of two separated diamonds, two separated rectangles and two separated circles.

Referring to FIGS. 15A and 15B, the photosensitive layer 370 is developed so that an unexposed region of the photosensitive layer 370 is removed and the exposed region remains, whereby a photosensitive pattern 370c is formed. The insulating layer is etched using the photosensitive pattern 370c as a mask. Therefore, a protrusion 360b is formed on a predetermined portion of the black matrix 320. The protrusion 360b may be formed, for example, for every three pixels.

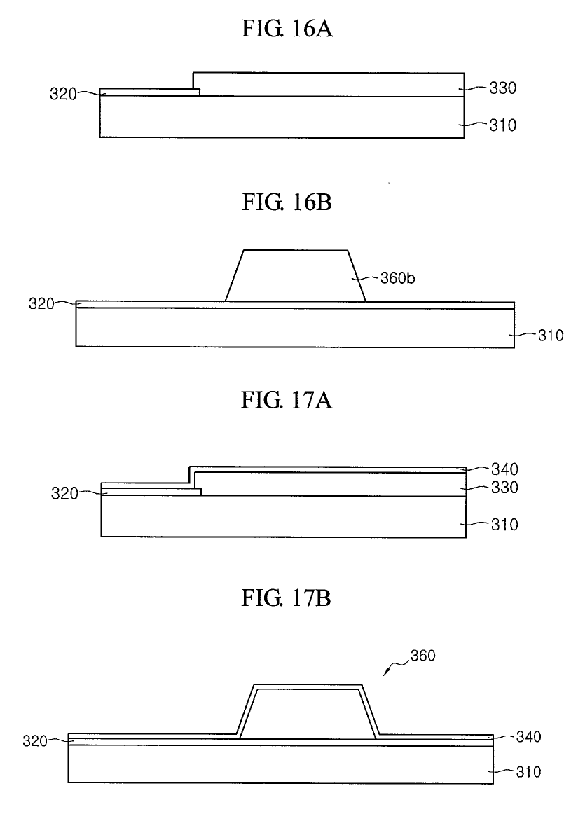

Referring to FIGS. 16A and 16B, the photosensitive pattern 370c is removed, and thereafter a plurality of color filters 330, e.g., red, green and blue color filters, are formed over the substrate 310 on which the black matrix 320 and the protrusion 360b are formed. During a process of forming the color filter 330, a negative color resist in which red pigment is dispersed is coated onto the substrate 310, and is then exposed using a third mask exposing a region where the red color filter will be formed. Subsequently, the negative color resist is developed using a development solution so that the exposed region is not removed and remains as a pattern. Only the unexposed region is removed. The red color filter 330 is formed in this way on the substrate 310. Likewise, the blue and green color filters may be formed through the above-described process.

Referring to FIGS. 17A and 17B, a conductive layer is formed on an entire surface of a resultant structure including the substrate 310 where the plurality of color filters 330 and the protrusion 360b are formed. The conductive layer is formed using a transparent conductive layer including ITO or IZO. The conductive layer is formed using a sputtering or the like. As such, a common electrode 340 is formed on an entire surface of the substrate 310. In addition, the conductive layer is also formed on the protrusion 360b, which forms a conductive spacer 360. An over-coating layer may be formed over the plurality of color filters 330 so as to achieve good step coverage during forming the common electrode 340.

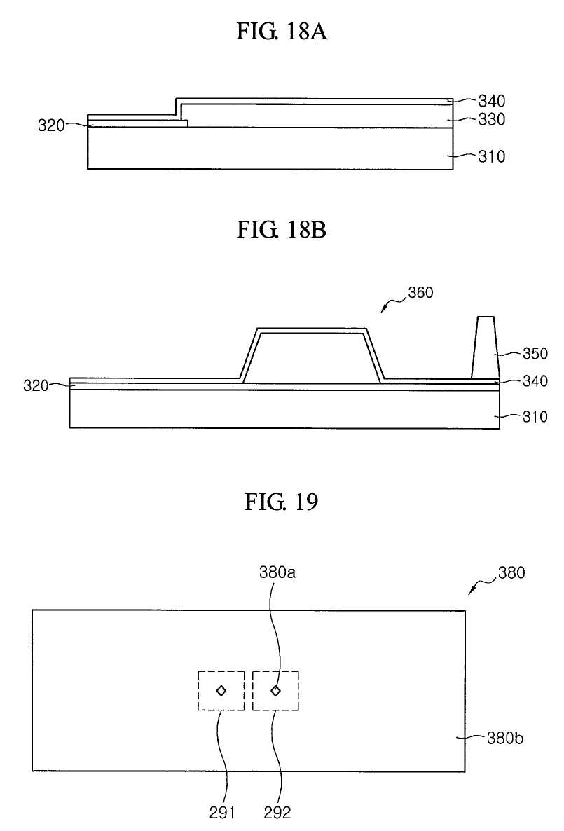

Referring to FIGS. 18A and 18B, an organic material is formed on an entire surface of a resultant structure including the substrate 310. Thereafter, a photolithography process is performed on the resultant structure to thereby form a cell gap spacer 350 using a fourth mask. The cell gap spacer 350 is formed on the black matrix 320.

In the various embodiments of the present disclosure, although the photosensitive layer 370 is formed on the insulating layer 360a which is not photosensitive, the insulating layer 360a itself may be photosensitive. In this case, an exposure process may be performed on the insulating layer 360a without the formation of the photosensitive layer 370. Further, the various embodiments presented herein illustrate that the color filter 330 is formed after the protrusion 360a is formed, but the present disclosure is not limited thereto. That is, the protrusion 360b may be formed after the color filter is formed first.

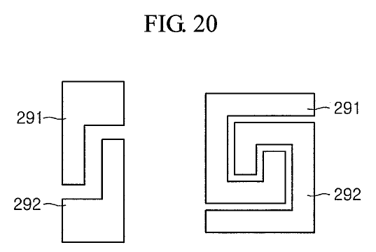

Although the foregoing embodiments illustrate that the cell gap spacer 350 is formed on the upper substrate 300, the cell gap spacer 350 may be formed on the lower substrate 200. Moreover, the embodiments illustrate that the sensing electrode is divided into the first and second sensing electrodes 291 and 292 which are spaced apart from each other, but the sensing electrode may be a single electrode that is not divided or separated. Furthermore, the first and second sensing electrodes 291 and 292 have a shape of rectangle but they may also be shaped so that they contact each other. For example, portions of the first and second sensing electrodes 291 and 292 may protrude from an upper region and a lower region thereof, respectively, and the protruding portions of the first and second sensing electrodes 291 and 292 may face each other, as illustrated in FIG. 20. Alternatively, the first and second sensing electrodes 291 and 292 may have bent portions so that the bent portions are disposed to approximately form a coil shape.

In accordance with various embodiments, a contact surface between a conductive spacer and first and second sensing electrodes can be increased by forming the conductive spacer such that it extends from regions corresponding to central portions of the first and second sensing electrodes that are spaced apart from each other. Therefore, it is possible to prevent a sensing failure caused by misalignment between the sensing electrode and the conductive spacer, thus improving touch sensitivity and reliability of a display.

Although the display and the method of manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A display comprising:
a first substrate and a second substrate facing each other;
a first sensing electrode and a second sensing electrode disposed on the first substrate, wherein the first and second sensing electrodes are spaced apart from each other; and
a conductive spacer disposed on the second substrate, wherein the conductive spacer is disposed so as to correspond to each of the first and second sensing electrodes.

2. The display of claim 1, wherein the first substrate comprises:
a first sensing line arranged in one direction of the first substrate; and
a second sensing line intersecting the first sensing line, the first and second sensing lines being insulated from each other.

3. The display of claim 2, wherein the first and second sensing electrodes are connected to the first and second sensing lines, respectively.

4. The display of claim 3, wherein the second sensing line is provided for one or more unit pixels.

5. The display of claim 1, wherein the cross section of the conductive spacer becomes wider as it extends from a region corresponding to a center of each of the first and second sensing electrodes toward a region corresponding to outer edges of the first and second sensing electrodes.

6. The display of claim 5, wherein the cross section of the conductive spacer has a small width at a region between the first and second sensing electrodes.

7. The display of claim 6, wherein the cross section of the conductive spacer has a maximum width at a region corresponding to the each center of the first and second sensing electrodes.

8. The display of claim 1, wherein the conductive spacer has cross sections that are spaced apart from each other and the cross sections have wider regions corresponding to the each central portions of the first and second sensing electrodes.

9. The display of claim 1, wherein the conductive spacer comprises two spacers that are spaced apart from each other.

10. The display of claim 9, wherein the conductive spacer is provided for one or more unit pixels, and is disposed on a black matrix.

11. The display of claim 1, wherein portions of the first and second sensing electrodes extend to cross each other.

12. A method of manufacturing a display, the method comprising:
forming first and second sensing lines and first and second sensing electrodes connected to the first and second sensing lines, respectively, on a first substrate, wherein the first and second sensing lines extend in a first direction and a second direction, respectively, and are insulated from each other;
forming a conductive spacer on a second substrate, the conductive spacer formed on a region corresponding to each of the first and second sensing electrodes;
forming a cell gap spacer between the first and second substrates; and
forming a liquid crystal layer between the first and second substrates.

13. The method of claim 12, wherein forming the first and second sensing lines comprises:
forming a plurality of gate lines extending in the first direction and the first sensing line spaced apart from the plurality of gate lines on the first substrate;
forming a gate insulating layer on the first substrate, and forming an active layer and an ohmic contact layer on a predetermined region of the gate insulating layer;
forming a plurality of data lines extending in the second direction, the second sensing line spaced apart from the plurality of data lines on the gate insulating layer;
forming a passivation layer on the substrate, and etching a predetermined region of the passivation layer to form a plurality of contact holes; and
forming a pixel electrode on the passivation layer, and forming the sensing electrode connected to the first and second sensing lines.

14. The method of claim 12, wherein forming the conductive spacer comprises:
forming a black matrix on a predetermined region of the second substrate;
forming a protrusion extending along the sensing electrode in a region corresponding to the sensing electrode on the second substrate, and forming a color filter; and
forming a conductive layer on the second substrate, and patterning the conductive layer to form a common electrode and a conductive spacer.

15. The method of claim 14, wherein the protrusion is formed by a photolithography process using a mask exposing regions corresponding to respective central portions of the first and second sensing electrodes.

16. The method of claim 14, wherein the protrusion comprises two protrusions spaced apart from each other.
